(19) United States
(12) Patent Application Publication
(10) Pub. No.: US 2026/0334238 A1
(43) Pub. Date: Oct. 22, 2026

(54) SEMICONDUCTOR-ON-INSULATOR (SOI) STRUCTURE WITH VARIABLE RESISTIVITY EPITAXIAL SEMICONDUCTOR LAYERS AND METHODS OF MAKING THE SAME

(71) Applicant: Taiwan Semiconductor Manufacturing Company Limited, Hsinchu (TW)

(72) Inventors: Yun-Chi Wu, Tainan City (TW); Po-Wei Liu, Tainan City (TW); Ping-Cheng Li, Kaohsiung City (TW); Yu-Hung Cheng, Tainan City (TW); Yung-Lung Lin, Taichung City (TW)

(21) Appl. No.: 19/730,898

(22) Filed: Jul. 3, 2026

Related U.S. Application Data
(62) Division of application No. 18/424,960, filed on Jan. 29, 2024.

(51) Int. Cl. H10W 44/00; H10P 14/60; H10P 50/28; H10P 50/64

(52) U.S. Cl. CPC H10W 44/401; H10P 14/6548; H10P 50/283; H10P 50/642

(57) ABSTRACT

Semiconductor-on-insulator (SOI) structures with variable resistivity epitaxial semiconductor layers and methods of making the same are disclosed. The SOI structures may include customized resistivity profiles without changing the epitaxial structure of vendor-supplied base materials or requiring the development of new etching chemistries. An SOI structure may be formed by forming a second epitaxial semiconductor layer over a first epitaxial semiconductor layer on a first substrate, where the resistivity of the second epitaxial semiconductor layer is different than the resistivity of the first epitaxial semiconductor layer, forming a dielectric capping layer over the second epitaxial semiconductor layer, bonding the dielectric capping layer to a second dielectric capping layer on a second substrate, and removing the first substrate to provide the SOI structure. An optional third epitaxial semiconductor layer may be formed over the first epitaxial semiconductor layer.

### RELATED APPLICATIONS

This application is a divisional of U.S. patent application Ser. No. 18/424,960, filed Jan. 29, 2024, entitled “Semiconductor-On-Insulator (SOI) Structure With Variable Resistivity Epitaxial Semiconductor Layers And Methods Of Making The Same,” the entire contents of which are hereby incorporated by reference for all purposes.

### BACKGROUND

Bipolar/CMOS/DMOS (BCD) devices include a bipolar region that may perform analog functions, a complementary metal oxide semiconductor (CMOS) region that may perform digital functions, and a double diffused metal oxide semiconductor (DMOS) region that may include high-power and high-voltage elements to provide power. BCD devices are used for a number of applications, such as for communications applications, automotive applications, and the like. By integrating three distinct types of components on a single die, BCD technology may reduce the number of components in the bill of materials (BoM). Fewer chip components in the BoM further reduces the area on the board, thus driving down costs. However, integrating different types of components that operate at different voltages on a single die can present challenges.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a vertical cross-section view of an exemplary intermediate structure including a first epitaxial semiconductor layer located over a first substrate according to various embodiments of the present disclosure.

FIG. 2 is a vertical cross-section view of an exemplary intermediate structure including a second epitaxial semiconductor layer located over the first epitaxial semiconductor layer according to various embodiments of the present disclosure.

FIG. 3 is a vertical cross-section view of an exemplary intermediate structure including a first dielectric capping layer located over the second epitaxial semiconductor layer according to various embodiments of the present disclosure.

FIG. 4 is a vertical cross-section view of an exemplary intermediate structure including a second substrate according to various embodiments of the present disclosure.

FIG. 5 is a vertical cross-section view of an exemplary intermediate structure including a second dielectric capping layer located over the second substrate according to various embodiments of the present disclosure.

FIG. 6 is a vertical cross-section view of an exemplary intermediate structure illustrating a surface treatment being performed on the outer surface of the first dielectric capping layer according to various embodiments of the present disclosure.

FIG. 7 is a vertical cross-section view of an exemplary intermediate structure illustrating a surface treatment being performed on the outer surface of the second dielectric capping layer according to various embodiments of the present disclosure.

FIG. 8 is a vertical cross-section view of an exemplary intermediate structure illustrating the outer surface of the second dielectric capping layer aligned over the outer surface of the first dielectric capping layer according to various embodiments of the present disclosure.

FIG. 9 is a vertical cross-section view of an exemplary intermediate structure following a bonding process that bonds the first dielectric capping layer to the second dielectric capping layer according to various embodiments of the present disclosure.

FIG. 10 is a vertical cross-section view of an exemplary intermediate structure illustrating the first substrate, the first epitaxial semiconductor layer, the second epitaxial semiconductor layer and the buried insulator layer located over the second substrate according to various embodiments of the present disclosure.

FIG. 11 is a vertical cross-section view of a semiconductor-on-insulator (SOI) structure according to various embodiments of the present disclosure.

FIG. 12 is a vertical cross-section view of a semiconductor-on-insulator (SOI) structure including a third epitaxial semiconductor layer over the first epitaxial semiconductor layer according to various embodiments of the present disclosure.

FIG. 13 is a vertical cross-section view of a semiconductor device formed using an SOI structure according to various embodiments of the present disclosure.

FIG. 14 is a flow chart illustrating steps of a method of forming a semiconductor-on-insulator (SOI) structure according to various embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the structure in use or operation in addition to the orientation depicted in the figures. The apparatus may be otherwise oriented (rotated 90 degrees or at other orientations) and the spatially relative descriptors used herein may likewise be interpreted accordingly.

The present disclosure is directed to semiconductor structures, and specifically to semiconductor-on-insulator (SOI) structures with variable resistivity epitaxial semiconductor layers and methods of making the same.

In recent years, many semiconductor chip designers have focused their efforts on integrating different types of semiconductor devices on a single integrated circuit (IC) die (i.e., a chip). For example, a single semiconductor chip, such as a BCD chip, may have an analog region including bipolar junction transistors, a digital logic region including complementary metal oxide semiconductor (CMOS) transistors, and a power region including double diffused metal oxide semiconductor (DMOS) transistors. By combining functionality that had previously been on separate chips into a single integrated chip, the number of chips may be reduced. Consequently, real estate on circuit boards may be freed up as fewer chips may be required. Thus, the cost of assembly may also be lowered.

However, the various semiconductor devices placed in close proximity to one another may utilize different voltages in operation. For example, in some embodiments, the DMOS transistors may have an operating voltage in a range from 50 volts to 1,000 volts. In contrast, the bipolar or CMOS transistor devices may have an operating voltage less than 50 V, and/or less than 24 V, and/or less than 12 V, and/or less than 6 V. Placing these high-voltage devices and low-voltage devices in close proximity on a single die may result in the different devices interfering with, or even damaging, one another. Thus, techniques to isolate the high voltage devices from the low voltage devices may be employed.

One technique that may be utilized to provide isolation between different components in a semiconductor device, such as a BCD chip, is by fabricating the components of the device using a semiconductor-on-insulator (SOI) structure. An SOI structure includes a buried insulator layer, such as an oxide layer, located between an upper device layer composed of an epitaxial semiconductor material (e.g., single-or polycrystalline silicon) and a lower substrate that may be composed of a semiconductor material (e.g., bulk silicon). An SOI structure may provide a number of advantages. For example, an SOI structure may provide improved isolation between devices, with reduced crosstalk and noise between the different devices. In addition, an SOI structure may operate with a reduced power consumption by reducing leakage current and capacitive coupling. In addition, the SOI structure may provide faster switching speeds for both CMOS and DMOS components, and reduced susceptibility to latch-up issues.

However, manufacturers of SOI-based devices may be limited by the availability of the base materials used to fabricate the SOI structures. Vendors of epitaxial semiconductor (e.g., silicon) materials typically provide only a limited selection of the materials having specified characteristics, such as a specific bulk resistivity. Often the bulk resistivities of the commercially-available epitaxial semiconductor materials may be suitable for one type of device (e.g., CMOS and/or bipolar devices) but may not be acceptable for other types of devices (e.g., DMOS devices), thus limiting their applicability for BCD chips. Making changes to the vendor-provided materials may result in unwanted modifications to the epitaxial structure of the material and introduce additional processing complexities, such as necessitating the development and validation of new etching chemistries and/or processes. While it may be possible to request customized epitaxial semiconductor materials from an outside vendor, this may present challenges in terms of purchasing ability and vendor delivery schedule that may introduce uncertainty and delays in the device manufacturing process.

Various embodiments of the present disclosure include SOI structures with variable resistivity epitaxial semiconductor layers and methods of making the same. In accordance with various embodiments of the present disclosure, SOI structures may include customized resistivity profiles without changing the epitaxial structure of vendor-supplied base materials or requiring the development of new etching chemistries. In some embodiments, an SOI structure may be formed by forming a second epitaxial semiconductor layer over a first epitaxial semiconductor layer on a first substrate, where the resistivity of the second epitaxial semiconductor layer may be different than the resistivity of the first epitaxial semiconductor layer, forming a first dielectric capping layer over the second epitaxial semiconductor layer, bonding the first dielectric capping layer to a second dielectric capping layer located on a second substrate, and removing the first substrate to provide a semiconductor-on-insulator SOI structure with variable resistivity epitaxial semiconductor layers. The SOI structure may include the first epitaxial semiconductor layer and the second epitaxial semiconductor layer on the second substrate, and a buried insulator layer formed by the first dielectric capping layer and the second dielectric capping layer located between the second epitaxial semiconductor layer and the second substrate.

In some embodiments, a third epitaxial semiconductor layer may be formed over the first epitaxial semiconductor layer to provide a desired total thickness for the epitaxial semiconductor material of the SOI structure. The third epitaxial semiconductor layer may have a resistivity that is the same or substantially the same as the first epitaxial semiconductor layer. Alternatively, the third epitaxial semiconductor layer may have a resistivity that is different from the resistivity of the first epitaxial semiconductor layer. In some embodiments, the third epitaxial semiconductor layer may have a resistivity that is the same or substantially the same as the second epitaxial semiconductor layer.

In some embodiments, the resistivity of the second epitaxial semiconductor layer may be greater than the resistivities of the first epitaxial semiconductor layer and the optional third epitaxial semiconductor layer by a factor of at least two, such as by a factor of at least five, including by a factor of ten or more. Providing the relatively high resistivity second epitaxial semiconductor layer underlying the relatively lower resistivity first and third epitaxial semiconductor layers may provide improved performance, including a higher breakdown voltage. SOI structures according to various embodiments may be used to form high-voltage devices, such as BCD devices, that may successfully integrate lower-voltage bipolar and/or CMOS transistors and high-voltage (e.g., >50V) DMOS power components on a single chip.

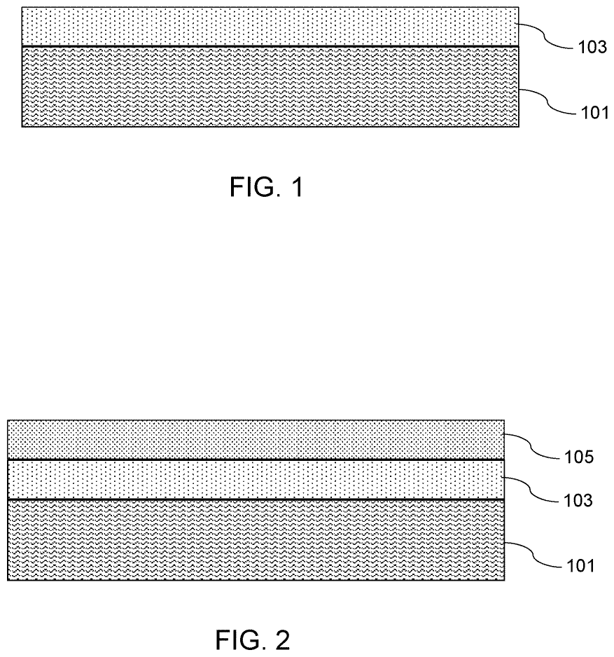

FIGS. 1-12 are sequential vertical cross-section views illustrating a process of fabricating a SOI structure according to various embodiments of the present disclosure. FIG. 1 is a vertical cross-section view of an exemplary intermediate structure including a first epitaxial semiconductor layer 103 located over a first substrate 101. The first substrate 101 may include a semiconductor material. In some embodiments, the semiconductor material of the first substrate 101 may include at least one Group IV element such as silicon, germanium, and/or carbon. In some embodiments, the semiconductor material of the first substrate 101 may include a compound semiconductor material (e.g., a III-V compound semiconductor material and/or a II-VI compound semiconductor material), and/or an organic semiconductor material. Other suitable materials for the first substrate 101 are within the contemplated scope of disclosure.

In some embodiments, the semiconductor material of the first substrate 101 may include, and/or may consist essentially of, intrinsic silicon, p-doped silicon, n-doped silicon, an intrinsic silicon-germanium alloy, a p-doped silicon-germanium alloy, or an n-doped silicon-germanium alloy. In embodiments in which the semiconductor material of the first substrate 101 may include electrical dopants (such as p-type dopants or n-type dopants), the atomic concentration of the electrical dopants in the semiconductor material of the first substrate 101 may be in a range from 1.0×10¹³/cm³ to 1.0×10²⁰/cm³, such as from 1.0×10¹⁶/cm³ to 1.0×10²⁰/cm³, although lesser and greater atomic concentrations may also be used.

The first substrate 101 may have a thickness that is sufficient to provide sufficient mechanical support such that the first substrate 101 may be handled in standard semiconductor processing equipment. For example, thickness of the first substrate 101 may be in a range from 100 microns to 2 mm, such as from 300 microns to 1 mm, although lesser and greater thicknesses may also be used.

In various embodiments, the semiconductor material of the first substrate 101 may be crystalline semiconductor material, such as single crystalline semiconductor material (e.g., single crystalline silicon). In some embodiments, the entirely of the first substrate 101 may be a single crystalline semiconductor material and may have the same set of crystallographic orientations throughout.

Referring again to FIG. 1, the first epitaxial semiconductor layer 103 may be located over the first substrate 101. The first epitaxial semiconductor layer 103 may be composed of a semiconductor material, such as a Group IV element (e.g., silicon, germanium, etc.), a compound semiconductor material (e.g., a III-V compound semiconductor material and/or a II-VI compound semiconductor material), and/or an organic semiconductor material. Other suitable materials for the first epitaxial semiconductor layer 103 are within the contemplated scope of disclosure. In some embodiments, the semiconductor material of the first epitaxial semiconductor layer 103 may include the same semiconductor material as the first substrate 101. Alternatively, the semiconductor material of the first epitaxial semiconductor layer 103 may be different than the semiconductor material of the first substrate 101.

In various embodiments, the semiconductor material of the first epitaxial semiconductor layer 103 may be crystalline semiconductor material, such as single crystalline semiconductor material (e.g., single crystalline silicon). In some embodiments, the crystallographic orientations of the first epitaxial semiconductor layer 103 may correspond to the crystallographic orientations of the underlying semiconductor material of the first substrate 101. The first epitaxial semiconductor layer 103 may be formed over the first substrate 101 using a suitable deposition method, such as chemical vapor deposition (CVD), low-pressure chemical vapor deposition (LPCVD), metalorganic chemical vapor deposition (MOCVD), plasma-enhanced chemical vapor deposition (PECVD), molecular beam epitaxy (MBE), liquid phase epitaxy (LPE), atomic layer deposition (ALD), physical vapor deposition (PVD), and the like. Other suitable deposition methods are within the contemplated scope of disclosure. Because the first epitaxial semiconductor layer 103 may be formed (e.g., epitaxially grown) on the first substrate 101, the first substrate 101 may also be referred to as a “growth substrate” 101.

In various embodiments, the first epitaxial semiconductor layer 103 may be a doped semiconductor layer including dopants of a first conductivity type (i.e., p-type or n-type). In some embodiments, a net atomic concentration of electrical dopants (i.e., p-type dopants and/or n-type dopants) in the first epitaxial semiconductor layer 103 may be in a range from 1.0×10¹³/cm³ to 1.0×10¹⁸/cm³, such as from 1.0×10¹⁴/cm³ to 1.0×10¹⁷/cm³, although lesser and greater atomic concentrations may also be used. Suitable p-type dopants may include, for example, boron, aluminum, gallium, and indium. Suitable n-type dopants may include, for example, phosphorus, antimony, arsenic, bismuth, and lithium. Other suitable p-type and n-type dopants are within the contemplated scope of disclosure.

In various embodiments, the net concentration of electrical dopants (i.e., p-type dopants and/or n-type dopants) in the first epitaxial semiconductor layer 103 may be different than the net atomic concentration of electrical dopants (i.e., p-type dopants and/or n-type dopants) in the semiconductor material of the underlying first substrate 101. In some embodiments, the first epitaxial semiconductor layer 103 may be composed of a first conductivity-type (i.e., p-type or n-type) semiconductor material having a first concentration of electrical dopants, and the first substrate 101 may include a first conductivity-type (i.e., p-type or n-type) semiconductor material having a second concentration of electrical dopants that is greater than the first concentration of electrical dopants. In other words, the semiconductor material of the first epitaxial semiconductor layer 103 may be more lightly-doped with dopants of the first conductivity-type than is the semiconductor material of the first substrate 101. In one non-limiting embodiment, the first epitaxial semiconductor layer 103 may include a lightly-doped p-type semiconductor material (e.g., P− silicon) and the first substrate 101 may be a heavily-doped p-type semiconductor material (e.g., P+ silicon). In various embodiments, the different doping profiles of the semiconductor material of the first substrate 101 and the first epitaxial semiconductor layer 103 may provide for improved etch selectivity during a subsequent etching step to be described in further detail below.

In some embodiments, the first epitaxial semiconductor layer 103 may have a thickness between 0.1 μm and 10 μm, such as between 2 μm and 6 μm (e.g., ~4 μm), although greater and lesser thicknesses for the first epitaxial semiconductor layer 103 may also be utilized. The first epitaxial semiconductor layer 103 may have a first bulk resistivity. The first bulk resistivity may be between about 0.1 Ω-cm and about 200 Ω-cm, such as between about 5 Ω-cm and about 150 Ω-cm. The bulk resistivity of the first epitaxial semiconductor layer 103 may be a function of the particular semiconductor material of the first epitaxial semiconductor layer 103 as well as the concentration of electrical dopants in the semiconductor material of the first epitaxial semiconductor layer 103. Thus, in some embodiments, the bulk resistivity of the first epitaxial semiconductor layer 103 may be controlled, at least in part, by controlling the concentration of electrical dopants within the semiconductor material of the first epitaxial semiconductor layer 103.

An exemplary intermediate structure as shown in FIG. 1 may be used to manufacture an SOI structure as described in further detail below. In many cases, a structure as shown in FIG. 1 may be available from commercial suppliers (i.e., vendors) as a standard product having a uniform set of characteristics. For example, a vendor may sell a product including a P+ silicon substrate 101 and a P− epitaxial silicon layer 103 formed thereon, where the P− epitaxial silicon layer 103 may have a particular resistivity, such as 10 Ω-cm. In some cases, the vendor may sell limited variety of similar products having different characteristics, such as a first product including a P+ silicon substrate 101 with a P− epitaxial silicon layer 103 having a resistivity of 10 Ω-cm, and a second product including a P+ silicon substrate 101 with a P− epitaxial silicon layer 103 having a resistivity of 100 Ω-cm. As discussed above, such products may not be acceptable for integrating different types of devices, such as high-voltage power devices and/or low-voltage logic devices, on a single chip.

FIG. 2 is a vertical cross-sectional view of an exemplary intermediate structure including a second epitaxial semiconductor layer 105 located over the first epitaxial semiconductor layer 103 according to various embodiments of the present disclosure. Referring to FIG. 2, the second epitaxial semiconductor layer 105 may be composed of a semiconductor material, such as a Group IV element (e.g., silicon, germanium, etc.), a compound semiconductor material (e.g., a III-V compound semiconductor material and/or a II-VI compound semiconductor material), and/or an organic semiconductor material. Other suitable materials for the second epitaxial semiconductor layer 105 are within the contemplated scope of disclosure. In some embodiments, the semiconductor material of the second epitaxial semiconductor layer 105 may include the same semiconductor material as the first epitaxial semiconductor layer 103 and the first substrate 101. Alternatively, the semiconductor material of the second epitaxial semiconductor layer 105 may be different than the semiconductor material of the first epitaxial semiconductor layer 103 and/or the first substrate 101.

In various embodiments, the semiconductor material of the second epitaxial semiconductor layer 105 may be crystalline semiconductor material, such as single crystalline semiconductor material (e.g., single crystalline silicon). In some embodiments, the crystallographic orientations of the second epitaxial semiconductor layer 105 may correspond to the crystallographic orientations of the underlying first epitaxial semiconductor layer 103. The second epitaxial semiconductor layer 105 may be formed over the first epitaxial semiconductor layer 103 using a suitable deposition method, such as chemical vapor deposition (CVD), low-pressure chemical vapor deposition (LPCVD), metalorganic chemical vapor deposition (MOCVD), plasma-enhanced chemical vapor deposition (PECVD), molecular beam epitaxy (MBE), liquid phase epitaxy (LPE), atomic layer deposition (ALD), physical vapor deposition (PVD), and the like. Other suitable deposition methods are within the contemplated scope of disclosure.

In various embodiments, the second epitaxial semiconductor layer 105 may be a doped semiconductor layer including dopants of the first conductivity type (i.e., p-type or n-type). In some embodiments, a net atomic concentration of electrical dopants (i.e., p-type dopants and/or n-type dopants) in the second epitaxial semiconductor layer 105 may be in a range from 1.0×10¹³/cm³ to 1.0×10¹⁸/cm³, such as from 1.0×10¹⁴/cm³ to 1.0×10¹⁷/cm³, although lesser and greater atomic concentrations may also be used. Suitable p-type dopants may include, for example, boron, aluminum, gallium, and indium. Suitable n-type dopants may include, for example, phosphorus, antimony, arsenic, bismuth, and lithium. Other suitable p-type and n-type dopants are within the contemplated scope of disclosure. In some embodiments, the second epitaxial semiconductor layer 105 may be an undoped semiconductor layer that may have a high electrical resistivity.

The second epitaxial semiconductor layer 105 may have a second bulk resistivity. The second bulk resistivity may be between about 0.1 Ω-cm and about 200 Ω-cm, such as between about 5 Ω-cm and about 150 Ω-cm. The second bulk resistivity of the second epitaxial semiconductor layer 105 may be different than the first bulk resistivity of the first epitaxial semiconductor layer 103. In some embodiments, the second bulk resistivity of the second epitaxial semiconductor layer 105 may be greater than the first bulk resistivity of the first epitaxial semiconductor layer 103. In some embodiments, the second bulk resistivity of the second epitaxial semiconductor layer 105 may be greater than the first bulk resistivity of the first epitaxial semiconductor layer 103 by a factor of two or more, such as by a factor of three or more, by a factor of five or more, including by a factor of ten or more. In one non-limiting embodiment, the first epitaxial semiconductor layer 103 may be a p-type epitaxial silicon layer 103 having a bulk resistivity of ~10 Ω-cm, and the second epitaxial semiconductor layer 103 may be a p-type epitaxial silicon layer 105 having a bulk resistivity of ~100 Ω-cm.

In other embodiments, the second bulk resistivity of the second epitaxial semiconductor layer 105 may be less than the first bulk resistivity of the first epitaxial semiconductor layer 103, such as by a factor of two or more, by a factor of three or more, by a factor of five or more, or by a factor of ten or more.

In some embodiments, the net concentration of electrical dopants (i.e., p-type dopants and/or n-type dopants) in the second epitaxial semiconductor layer 105 may be different than the net atomic concentration of electrical dopants in the first epitaxial semiconductor layer 103. Thus, in embodiments in which the first epitaxial semiconductor layer 103 and the second epitaxial semiconductor layer 105 are composed of the same material (e.g., p-type silicon), the variation in the net concentration of electrical dopants may provide the variation in the resistivities of the respective first and second epitaxial semiconductor layers 103 and 105.

In some embodiments, the second epitaxial semiconductor layer 105 may have a thickness between 0.1 μm and 10 μm, such as between 2 μm and 6 μm (e.g., ~4 μm), although greater and lesser thicknesses for the second epitaxial semiconductor layer 105 may also be utilized. In some embodiments, the second epitaxial semiconductor layer 105 may have a thickness that is substantially equivalent to (e.g., within ±10% of) the thickness of the first epitaxial semiconductor layer 103.

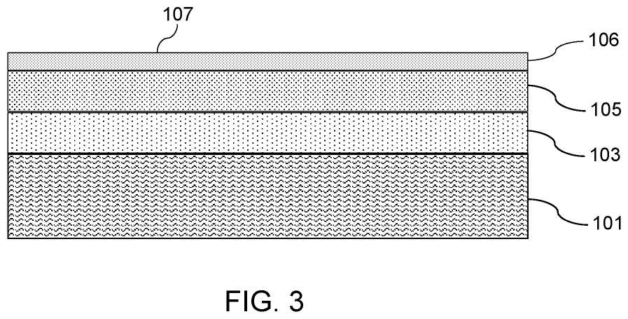

FIG. 3 is a vertical cross-section view of an exemplary intermediate structure including a first dielectric capping layer 106 located over the second epitaxial semiconductor layer 105 according to various embodiments of the present disclosure. Referring to FIG. 3, the first dielectric capping layer 106 may be composed of a suitable dielectric material, such as silicon oxide, silicon nitride, silicon oxynitride, aluminum oxide, etc., including combinations thereof. Other suitable dielectric materials are within the contemplated scope of disclosure. In some embodiments, the first dielectric capping layer 106 may be formed by performing a thermal oxidation process to provide the first dielectric capping layer 106 over the second epitaxial semiconductor layer 105. Alternatively, or in addition, the first dielectric capping layer 106 may be formed by depositing a dielectric material over the second epitaxial semiconductor layer 105 using a suitable deposition process, such as chemical vapor deposition (CVD), physical vapor deposition (PVD), atomic layer deposition (ALD), high density plasma CVD (HDPCVD), metalorganic CVD (MOCVD), plasma enhanced CVD (PECVD), sputtering, laser ablation, or the like.

In various embodiments, the first dielectric capping layer 106 may have a thickness that is between about 5 nm and about 1000 nm, such as between about 50 nm and 150 nm (e.g., ~100 nm), although greater and lesser thicknesses for the first dielectric capping layer 106 may also be utilized. The first dielectric capping layer 106 may have a planar outer surface 107 facing away from the underlying second epitaxial semiconductor layer 105 as shown in FIG. 3.

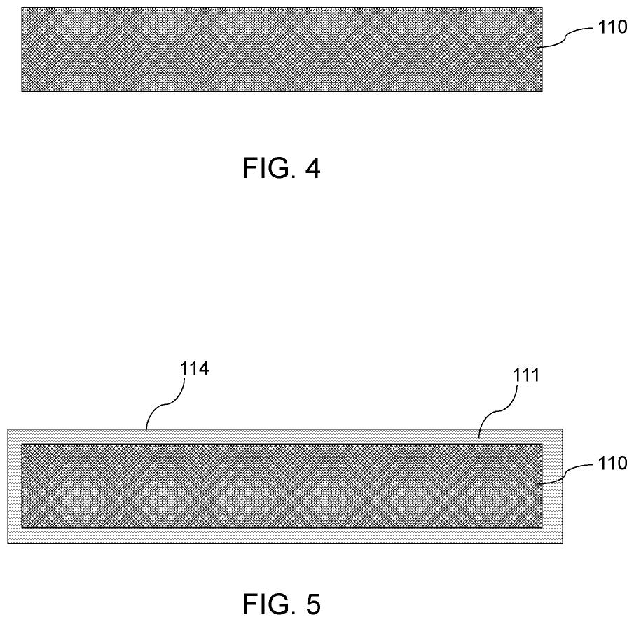

FIG. 4 is a vertical cross-section view of an exemplary intermediate structure including a second substrate 110 according to various embodiments of the present disclosure. The second substrate 110 may include a semiconductor material. In some embodiments, the semiconductor material of the second substrate 110 may include at least one Group IV element such as silicon, germanium, and/or carbon. In some embodiments, the semiconductor material of the second substrate 110 may include a compound semiconductor material (e.g., a III-V compound semiconductor material and/or a II-VI compound semiconductor material), and/or an organic semiconductor material. Other suitable materials for the second substrate 110 are within the contemplated scope of disclosure.

In some embodiments, the semiconductor material of the second substrate 110 may include, and/or may consist essentially of, intrinsic silicon, p-doped silicon, n-doped silicon, an intrinsic silicon-germanium alloy, a p-doped silicon-germanium alloy, or an n-doped silicon-germanium alloy. In some embodiments, the semiconductor material of the second substrate 110 may be single crystalline, polycrystalline, or amorphous. In embodiments in which the semiconductor material of the second substrate 110 may include electrical dopants (such as p-type dopants or n-type dopants), the atomic concentration of the electrical dopants in the semiconductor material of the second substrate 110 may be in a range from 1.0×10¹³/cm³ to 1.0×10¹⁸/cm³, such as from 1.0×10¹⁴/cm³ to 1.0×10¹⁷/cm³, although lesser and greater atomic concentrations may also be used.

The second substrate 110 may have a thickness that is sufficient to provide sufficient mechanical support such that the second substrate 110 may be handled in standard semiconductor processing equipment. For example, thickness of the second substrate 110 may be in a range from 100 microns to 2 mm, such as from 300 microns to 1 mm, although lesser and greater thicknesses may also be used. In some embodiments, the second substrate 110 may be a semiconductor wafer (e.g., a silicon wafer). As discussed in further detail below, the first dielectric capping layer 106, the second epitaxial semiconductor layer 105, and the first epitaxial semiconductor layer 103 shown in FIG. 3 may be transferred to the second substrate 110 during subsequent processing operations to form an SOI structure. Thus, the second substrate 110 may also be referred to as a “transfer substrate” and/or a “carrier substrate.”

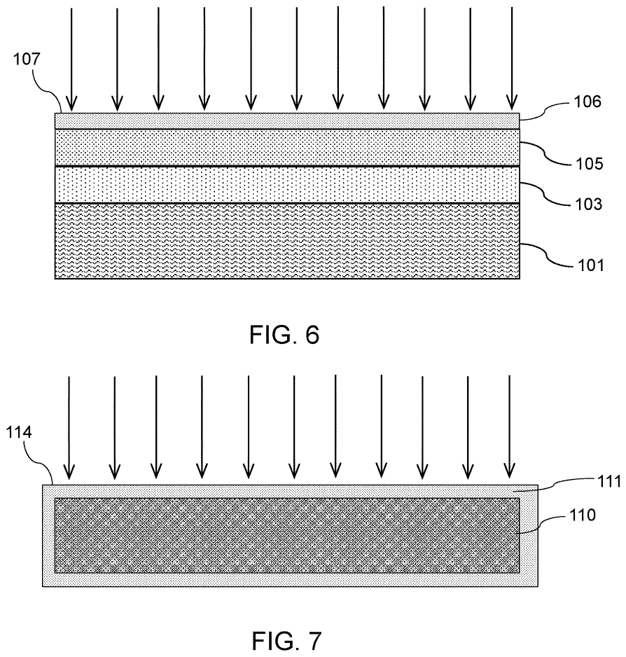

FIG. 5 is a vertical cross-section view of an exemplary intermediate structure including a second dielectric capping layer 111 located over the second substrate 110 according to various embodiments of the present disclosure. Referring to FIG. 5, the second dielectric capping layer 111 may be composed of a suitable dielectric material, such as silicon oxide, silicon nitride, silicon oxynitride, aluminum oxide, etc., including combinations thereof. Other suitable dielectric materials are within the contemplated scope of disclosure. In some embodiments, the second dielectric capping layer 111 may be composed of the same material(s) as the first dielectric capping layer 106 shown in FIG. 3.

In some embodiments, the second dielectric capping layer 111 may be formed by performing a thermal oxidation process to provide the second dielectric capping layer 111 over the second substrate 110. Alternatively, or in addition, the second dielectric capping layer 111 may be formed by depositing a dielectric material over the second substrate 110 using a suitable deposition process, such as chemical vapor deposition (CVD), physical vapor deposition (PVD), atomic layer deposition (ALD), high density plasma CVD (HDPCVD), metalorganic CVD (MOCVD), plasma enhanced CVD (PECVD), sputtering, laser ablation, or the like.

In various embodiments, the second dielectric capping layer 111 may have a thickness that is between about 5 nm and about 1000 nm, such as between about 100 nm and 300 nm (e.g., ~200 nm), although greater and lesser thicknesses for the second dielectric capping layer 111 may also be utilized. In some embodiments, the thickness of the second dielectric capping layer 111 may be greater than the thickness of the first dielectric capping layer 106. The second dielectric capping layer 111 may have a planar outer surface 114 as shown in FIG. 5.

FIG. 6 is a vertical cross-section view of an exemplary intermediate structure illustrating a surface treatment being performed on the outer surface 107 of the first dielectric capping layer 106 according to various embodiments of the present disclosure. Referring to FIG. 6, a precleaning process may be performed to remove particulates and other contaminants from the outer surface 107 of the first dielectric capping layer 106. Then, the outer surface 107 of the first dielectric capping layer 106 may be subjected to a plasma treatment at elevated temperature, as schematically indicated by the arrows in FIG. 6. In some embodiments, the plasma treatment may be performed at a temperature between about 200 °C and 400 °C, although greater and lesser temperatures may also be utilized. The plasma treatment may promote the formation of stronger chemical bonds during a subsequent dielectric-to-dielectric bonding process to be described in further detail below.

FIG. 7 is a vertical cross-section view of an exemplary intermediate structure illustrating a surface treatment being performed on the outer surface 114 of the second dielectric capping layer 111 according to various embodiments of the present disclosure. Referring to FIG. 7, a precleaning process may be performed to remove particulates and other contaminants from the outer surface 114 of the second dielectric capping layer 111. Then, the outer surface 114 of the second dielectric capping layer 111 may be subjected to a plasma treatment at elevated temperature, as schematically indicated by the arrows in FIG. 7. In some embodiments, the plasma treatment may be performed at a temperature between about 200 °C and 400 °C, although greater and lesser temperatures may also be utilized. The plasma treatment may promote the formation of stronger chemical bonds during the subsequent dielectric-to-dielectric bonding process to be described in further detail below. It will be understood that in some embodiments, one or both of the precleaning and plasma treatment steps described above with reference to FIGS. 6 and 7 may be omitted for the first dielectric capping layer 106 and/or the second dielectric capping layer 111.

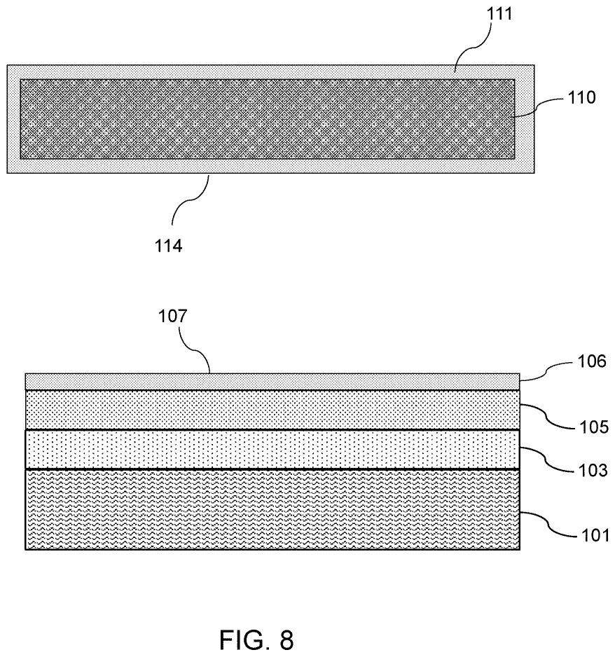

FIG. 8 is a vertical cross-section view of an exemplary intermediate structure illustrating the outer surface 114 of the second dielectric capping layer 111 aligned over the outer surface 107 of the first dielectric capping layer 106 according to various embodiments of the present disclosure. Referring to FIG. 8, in various embodiments, the second substrate 110 may be inverted (i.e., flipped over) relative to the orientation shown in FIGS. 5 and 7 such that the outer surface 114 of the second dielectric capping layer 111 may be located over and face towards the outer surface 107 of the first dielectric capping layer 106.

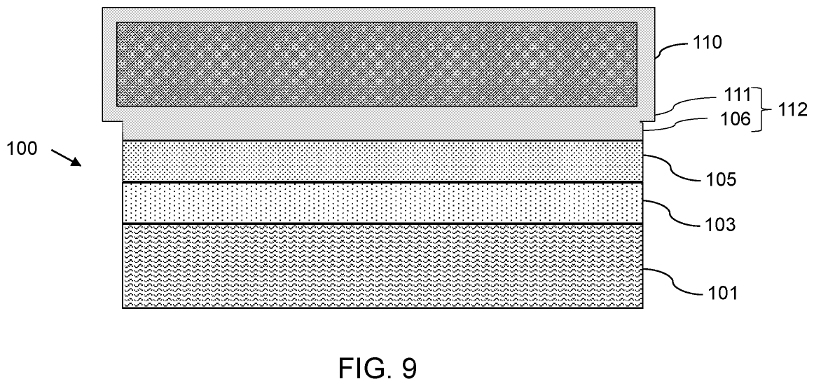

FIG. 9 is a vertical cross-section view of an exemplary intermediate structure following a bonding process that bonds the first dielectric capping layer 106 to the second dielectric capping layer 111 according to various embodiments of the present disclosure. Referring to FIG. 9, a dielectric-to-dielectric bonding process may be performed to bond the first dielectric capping layer 106 to the second dielectric capping layer 111. In various embodiments, an initial portion of the bonding process may include bringing the outer surface 114 of the second dielectric capping layer 111 into contact with the outer surface 107 of the first dielectric capping layer 106, which may result in the formation of chemical bonds between the second dielectric capping layer 111 and the first dielectric capping layer 106. In some embodiments, the initial portion of the bonding process may be performed in a vacuum chamber in a vacuum or reduced pressure environment. A subsequent heat treatment may be performed to strengthen the bond between the second dielectric capping layer 111 and the first dielectric capping layer 106. Following the bonding process, the bonded second dielectric capping layer 111 and first dielectric capping layer 106 may together form an insulator layer 112 located between the second epitaxial semiconductor layer 105 and the second substrate 110. The insulator layer 112 may form a buried insulator layer 112 of an SOI structure as described in further detail below.

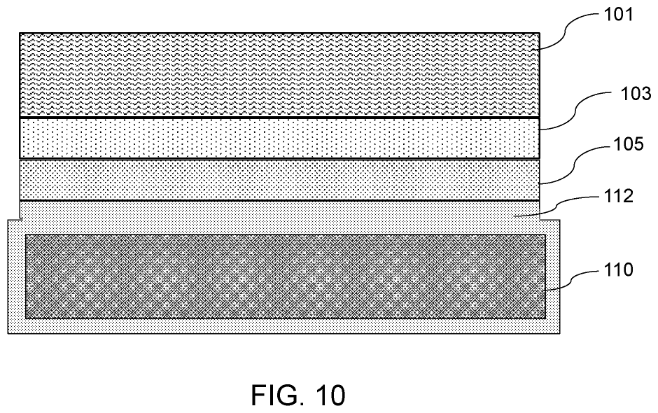

FIG. 10 is a vertical cross-sectional view of an exemplary intermediate structure illustrating the first substrate 101, the first epitaxial semiconductor layer 103, the second epitaxial semiconductor layer 105 and the buried insulator layer 112 located over the second substrate 110 according to various embodiments of the present disclosure. Referring to FIG. 10, the exemplary intermediate structure may be inverted (i.e., flipped over) relative to the orientation shown in FIG. 9 such that the first substrate 101, the first epitaxial semiconductor layer 103, the second epitaxial semiconductor layer 105, and the buried insulator layer 112 may be located over and may be supported by the second substrate 110.

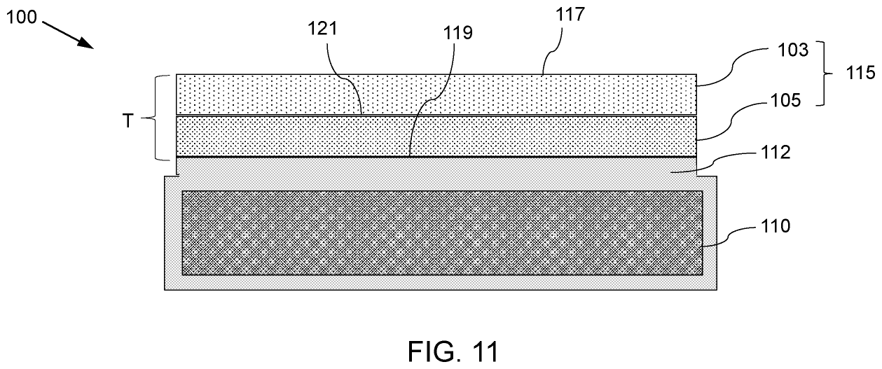

FIG. 11 is a vertical cross-sectional view of a semiconductor-on-insulator (SOI) structure 100 according to various embodiments of the present disclosure. In various embodiments, the first substrate 101 may be removed from the exemplary intermediate structure shown in FIG. 10 to provide an SOI structure 100 as shown in FIG. 11. In some embodiments, a thinning process may be performed to remove a portion of the first substrate 101. The thinning process may include, for example, a grinding process. Then, an etching process may be used to remove the remaining portion of the first substrate 101. The etching process may be a wet etching process that utilizes an etching chemistry having a higher etch selectivity for the semiconductor material of the first substrate 101 (e.g., P+ silicon) compared to the semiconductor material of the first epitaxial semiconductor layer 103 (e.g., P− silicon). This may facilitate stopping the etching process at the first epitaxial semiconductor layer 103. Following the etching process, an upper surface 117 of the first epitaxial semiconductor layer 103 may be exposed.

The SOI structure 100 shown in FIG. 11 includes the second substrate 110, an epitaxial semiconductor material portion 115 including the first epitaxial semiconductor layer 103 and the second epitaxial semiconductor layer 105, and a buried insulator layer 112 located between the epitaxial semiconductor material portion 115 and the second substrate 110. The SOI structure 100 may include a first interface 119 between the second epitaxial semiconductor layer 105 and the buried insulator layer 112, and a second interface 121 between the first epitaxial semiconductor layer 103 and the second epitaxial semiconductor layer 105. The epitaxial semiconductor material portion 115 may have a variable resistivity along a thickness dimension, T, between an upper surface 117 of the epitaxial semiconductor material portion 115 and the first interface 119. In some embodiments, the resistivity of the epitaxial semiconductor material portion 115 adjacent to the first interface 119 may be greater than the resistivity of the epitaxial semiconductor material portion 115 adjacent to the upper surface 117. In some embodiments, the resistivity of the epitaxial semiconductor material portion 115 adjacent to the first interface 119 may be greater than the resistivity of the epitaxial semiconductor material portion 115 adjacent to the upper surface 117 by a factor of two or more, such as by a factor of three or more, by a factor of five or more, including by a factor of ten or more. In one non-limiting embodiment, the resistivity of the epitaxial semiconductor material portion 115 adjacent to the upper surface 117 may be ~10 Ω-cm, and the resistivity of the epitaxial semiconductor material portion 115 adjacent to the first interface 119 may be ~100 Ω-cm.

In other embodiments, the resistivity of the epitaxial semiconductor material portion 115 adjacent to the first interface 119 may be less than the resistivity of the epitaxial semiconductor material portion 115 adjacent to the upper surface 117, such as by a factor of two or more, by a factor of three or more, by a factor of five or more, or by a factor of ten or more.

In some embodiments, the thickness, T, of the epitaxial semiconductor material portion 115 of the SOI structure 100 may be between 0.2 μm and 20 μm, such as between 4 μm and 12 μm (e.g., ~8 μm), although greater and lesser thicknesses for the epitaxial semiconductor material portion 115 may also be utilized.

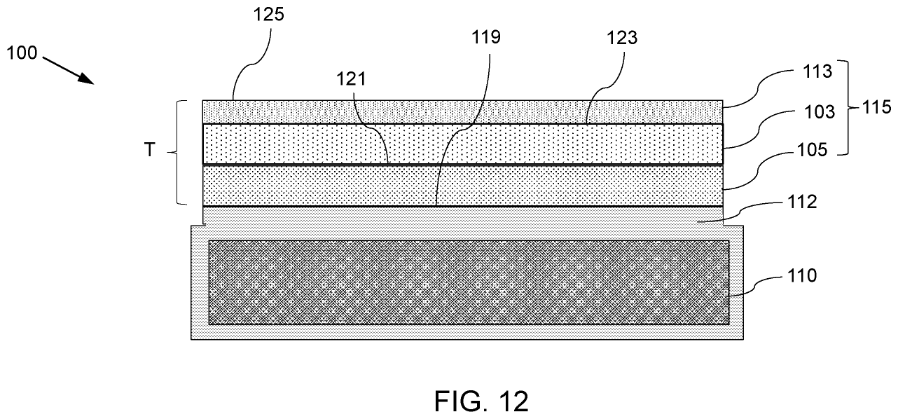

FIG. 12 is a vertical cross-section view of a semiconductor-on-insulator (SOI) structure 100 including a third epitaxial semiconductor layer 113 over the first epitaxial semiconductor layer 103 according to various embodiments of the present disclosure. Referring to FIG. 12, the third epitaxial semiconductor layer 113 may be composed of a semiconductor material, such as a Group IV element (e.g., silicon, germanium, etc.), a compound semiconductor material (e.g., a III-V compound semiconductor material and/or a II-VI compound semiconductor material), and/or an organic semiconductor material. Other suitable materials for the third epitaxial semiconductor layer 113 are within the contemplated scope of disclosure. In some embodiments, the semiconductor material of the third epitaxial semiconductor layer 113 may include the same semiconductor material as the first epitaxial semiconductor layer 103 and the second epitaxial semiconductor layer 105. Alternatively, the semiconductor material of the third epitaxial semiconductor layer 113 may be different than the semiconductor material of the first epitaxial semiconductor layer 103 and/or the second epitaxial semiconductor layer 105.

In various embodiments, the semiconductor material of the third epitaxial semiconductor layer 113 may be crystalline semiconductor material, such as single crystalline semiconductor material (e.g., single crystalline silicon). In some embodiments, the crystallographic orientations of the third epitaxial semiconductor layer 113 may correspond to the crystallographic orientations of the underlying first epitaxial semiconductor layer 103. The third epitaxial semiconductor layer 113 may be formed over the first epitaxial semiconductor layer 103 using a suitable deposition method, such as chemical vapor deposition (CVD), low-pressure chemical vapor deposition (LPCVD), metalorganic chemical vapor deposition (MOCVD), plasma-enhanced chemical vapor deposition (PECVD), molecular beam epitaxy (MBE), liquid phase epitaxy (LPE), atomic layer deposition (ALD), physical vapor deposition (PVD), and the like. Other suitable deposition methods are within the contemplated scope of disclosure.

In some embodiments, the bulk resistivity of the third epitaxial semiconductor layer 113 may be substantially equivalent to (e.g., within ±10% of) the bulk resistivity of the first epitaxial semiconductor layer 103. The bulk resistivity of the third epitaxial semiconductor layer 113 may be different from the bulk resistivity of the second epitaxial semiconductor layer 105, such as by a factor of two or more, by a factor of three or more, by a factor of five or more, or by a factor of ten or more. In various embodiments, the first epitaxial semiconductor layer 103, the second epitaxial semiconductor layer 105 and the third epitaxial semiconductor layer 113 may all include first conductivity-type (i.e., p-type or n-type) semiconductor material. In some embodiments, the net concentration of electrical dopants (i.e., p-type dopants and/or n-type dopants) in the third epitaxial semiconductor layer 113 may be substantially equivalent to (e.g., within ±10% of) the net atomic concentration of electrical dopants in the first epitaxial semiconductor layer 103, and may be different from the net atomic concentration of electrical dopants in the second epitaxial semiconductor layer 105.

In other embodiments, the third epitaxial semiconductor layer 113 may have a resistivity that is different from (e.g., >±10% from) the resistivity of the first epitaxial semiconductor layer 103. In some embodiments, the third epitaxial semiconductor layer 113 may have a resistivity that is the same or substantially the same (e.g., within ±10% of) the resistivity of the second epitaxial semiconductor layer 105.

In some embodiments, the third epitaxial semiconductor layer 113 may be formed to provide a desired total thickness, T, of the of the epitaxial semiconductor material portion 115 of the SOI structure 100. Thus, an SOI structure 100 as shown in FIG. 12 may include the second substrate 110, an epitaxial semiconductor material portion 115 including the third epitaxial semiconductor layer 113, the first epitaxial semiconductor layer 103 and the second epitaxial semiconductor layer 105, and a buried insulator layer 112 located between the epitaxial semiconductor material portion 115 and the second substrate 110. The SOI structure 100 may include a first interface 119 between the second epitaxial semiconductor layer 105 and the buried insulator layer 112, a second interface 121 between the first epitaxial semiconductor layer 103 and the second epitaxial semiconductor layer 105, and a third interface 123 between the first epitaxial semiconductor layer 103 and the third epitaxial semiconductor layer 113. The epitaxial semiconductor material portion 115 may have a variable resistivity along the thickness dimension, T, between an upper surface 125 of the epitaxial semiconductor material portion 115 and the first interface 119. In some embodiments, the resistivity of the epitaxial semiconductor material portion 115 adjacent to the first interface 119 may be greater than the resistivity of the epitaxial semiconductor material portion 115 adjacent to the upper surface 125. In some embodiments, the resistivity of the epitaxial semiconductor material portion 115 adjacent to the first interface 119 may be greater than the resistivity of the epitaxial semiconductor material portion 115 adjacent to the upper surface 125 by a factor of two or more, such as by a factor of three or more, by a factor of five or more, including by a factor of ten or more. In one non-limiting embodiment, the resistivity of the epitaxial semiconductor material portion 115 adjacent to the upper surface 125 may be ~10 Ω-cm, and the resistivity of the epitaxial semiconductor material portion 115 adjacent to the first interface 119 may be ~100 Ω-cm.

In some embodiments, the thickness, T, of the epitaxial semiconductor material portion 115 of the SOI structure 100 as shown in FIG. 12 may be between 0.5 μm and 25 μm, such as between 5 μm and 15 μm (e.g., ~9 μm), although greater and lesser thicknesses for the epitaxial semiconductor material portion 115 may also be utilized. In some embodiments, the thickness of the third epitaxial semiconductor layer 113 may be less than the thickness of the first epitaxial semiconductor layer 105 and the thickness of the second epitaxial semiconductor layer 105. In some embodiments, the thickness of the third epitaxial semiconductor layer 113 may be between 0.5 μm and 3 μm (e.g., ~1 μm), although greater and lesser thicknesses for the third epitaxial semiconductor layer 113 may also be utilized.

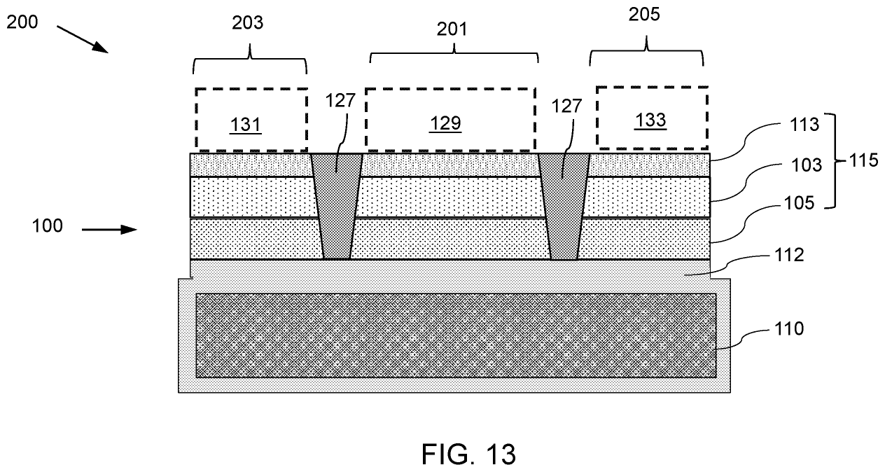

FIG. 13 is a vertical cross-section view of a semiconductor device 200 formed using an SOI structure 100 according to various embodiments of the present disclosure. Referring to FIG. 13, the semiconductor device 200 may include a plurality of device regions, including a first device region 201, a second device region 203, and a third device region 205. Isolation structures 127, such as isolation trenches 127 containing a dielectric material, may optionally be located between the respective device regions 201, 203 and 205.

At least one first device 129 may be formed on, and/or within portions of, the epitaxial semiconductor material portion 115 of the SOI structure 100 in the first device region 201. At least one second device 131 may be formed on, and/or within portions of, the epitaxial semiconductor material portion 115 of the SOI structure 100 in the second device region 203. At least one third device 133 may be formed on, and/or within portions of, the epitaxial semiconductor material portion 115 of the SOI structure 100 in the third device region 205. In one embodiment, the semiconductor device 200 may be a bipolar-CMOS-DMOS (BCD) device.

In some embodiments, the first region 201 of the semiconductor device 200 may be a high voltage region, which may include power devices. In various embodiments, the at least one first device 129 in the first region 201 may have an operating voltage that is greater than 50 volts, including greater than 90 volts, such as 100 volts or more. In some embodiments, the at least one first device 129 in the first region 201 may include at least one double diffused metal oxide semiconductor (DMOS) device.

In some embodiments, the second region 203 of the semiconductor device 200 may be a low voltage region, such as a low voltage analog region and/or a low voltage digital region. In various embodiments, the at least one second device 131 in the second region 203 may have an operating voltage that is less than 50 volts, including less than 24 volts, such as less than 6 volts. In some embodiments, the at least one second device 131 in the second region 203 may include at least one bipolar junction transistor and/or at least one complementary metal oxide semiconductor (CMOS) field effect transistor.

In some embodiments, the third region 205 of the semiconductor device 200 may be a low voltage region, such as a low voltage analog region and/or a low voltage digital region. In various embodiments, the at least one third device 133 in the third region 205 may have an operating voltage that is less than 50 volts, including less than 24 volts, such as less than 6 volts. In some embodiments, the at least one third device 133 in the third region 205 may include at least one bipolar junction transistor and/or at least one complementary metal oxide semiconductor (CMOS) field effect transistor. In some embodiments, both the second region 203 and the third region 205 of the semiconductor device 200 may include low voltage bipolar junction transistors. In some embodiments, both the second region 203 and the third region 205 of the semiconductor device 200 may include low voltage complementary metal oxide semiconductor (CMOS) field effect transistors.

The SOI structure 100 of the semiconductor device 200 shown in FIG. 13 may have an epitaxial semiconductor material portion 115 having a varying resistivity along a thickness of the epitaxial semiconductor material portion 115. In some embodiments, a resistivity of the second epitaxial semiconductor layer 105 may be greater than the resistivity of the first epitaxial semiconductor layer 103 and/or the third epitaxial semiconductor layer 113 by a factor of two or more, such as by a factor of five or more, including by a factor of ten or more. An SOI structure 100 as shown in FIG. 13 may provide increased breakdown voltage. In some embodiments, the breakdown voltage of the semiconductor device 200 shown in FIG. 13 may be at least 170 volts, such as 175 volts, including 180 volts or more. This may facilitate the integration of high-voltage power devices and low-voltage analog and/or digital logic devices in a single semiconductor device 200.

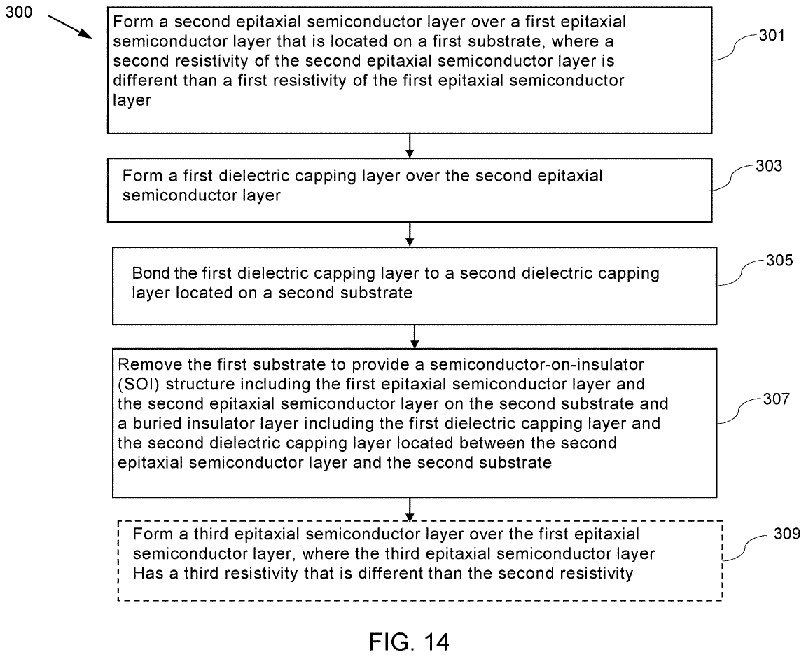

FIG. 14 is a flow chart illustrating steps of a method 300 of forming a semiconductor-on-insulator (SOI) structure according to various embodiments of the present disclosure. Referring to FIGS. 2 and 14, in step 301 of method 300, a second epitaxial semiconductor layer 105 may be formed over a first epitaxial semiconductor layer 103 that is located on a first substrate 101, where a second resistivity of the second epitaxial semiconductor layer 105 is different than a first resistivity of the first epitaxial semiconductor layer 103. Referring to FIGS. 3 and 14, in step 303 of method 300, a first dielectric capping layer 106 may be formed over the second epitaxial semiconductor layer 105. Referring to FIGS. 4-10 and 14, in step 305 of method 300, the first dielectric capping layer 106 may be bonded to a second dielectric capping layer 111 located on a second substrate 110. Referring to FIGS. 11 and 14, in step 307 of method 300, the first substrate 101 may be removed to provide an SOI structure 100 including the first epitaxial semiconductor layer 101 and the second epitaxial semiconductor layer 105 on the second substrate 110 and a buried insulator layer 112 including the first dielectric capping layer 106 and the second dielectric capping layer 111 located between the second epitaxial semiconductor layer 105 and the second substrate 110. Referring to FIGS. 12 and 14, in optional step 309 of method 300, a third epitaxial semiconductor layer 113 may be formed over the first epitaxial semiconductor layer 103, where a third resistivity of the third epitaxial semiconductor layer 113 is different than the second resistivity of the second epitaxial semiconductor layer 105.

Referring to all drawings and according to various embodiments of the present disclosure, a method of forming a semiconductor structure 100 includes forming a second epitaxial semiconductor layer 105 over a first epitaxial semiconductor layer 103 that is located on a first substrate 101, where a second resistivity of the second epitaxial semiconductor layer 105 is different than a first resistivity of the first epitaxial semiconductor layer 103, forming a first dielectric capping layer 106 over the second epitaxial semiconductor layer 105, bonding the first dielectric capping layer 106 to a second dielectric capping layer 111 located on a second substrate 110, and removing the first substrate 101 to provide a semiconductor-on-insulator (SOI) structure 100 including the first epitaxial semiconductor layer 103 and the second epitaxial semiconductor layer 105 on the second substrate 110, and a buried insulator layer 112 including the first dielectric capping layer 106 and the second dielectric capping layer 111 located between the second epitaxial semiconductor layer 105 and the second substrate 110.

In an embodiment, the second resistivity of the second epitaxial semiconductor layer 105 is greater than the first resistivity of the first epitaxial semiconductor layer 103.

In another embodiment, the second resistivity of the second epitaxial semiconductor layer 105 is greater than the first resistivity of the first epitaxial semiconductor layer 103 by a factor of at least two.

In another embodiment, the second resistivity of the second epitaxial semiconductor layer 105 is greater than the first resistivity of the first epitaxial semiconductor layer 103 by a factor of ten or more.

In another embodiment, the first substrate 101 includes a crystalline semiconductor material, and the first epitaxial semiconductor layer 103 includes a crystalline semiconductor material formed on the crystalline semiconductor material of the first substrate 101 by chemical vapor deposition (CVD), low-pressure chemical vapor deposition (LPCVD), metalorganic chemical vapor deposition (MOCVD), plasma-enhanced chemical vapor deposition (PECVD), molecular beam epitaxy (MBE), liquid phase epitaxy (LPE), atomic layer deposition (ALD), or physical vapor deposition (PVD).

In another embodiment, the first substrate 101 includes a semiconductor material that is doped with dopants of a first conductivity-type at a first doping concentration, and the first epitaxial semiconductor layer 103 is doped with dopants of the first conductivity-type at a second doping concentration that is less than the first doping concentration.

In another embodiment, removing the first substrate 101 includes performing a thinning process to remove a first portion of the first substrate 101, and performing an etching process to remove a remaining portion of the first substrate 101 using an etching chemistry having a higher etch selectivity for the first substrate 101 than for the first epitaxial semiconductor layer 103.

In another embodiment, the method further includes forming the second dielectric capping layer 111 over the second substrate 110, and performing a plasma treatment of at least one of the first dielectric capping layer 106 and the second dielectric capping layer 111 prior to bonding the first dielectric capping layer 106 to the second dielectric capping layer 111.

In another embodiment, bonding the first dielectric capping layer 106 to the second dielectric capping layer 111 includes performing a dielectric-to-dielectric bond in a vacuum or reduced pressure environment.

In another embodiment, the first epitaxial semiconductor layer 103 and the second epitaxial semiconductor layer 105 include the same semiconductor material that is doped with dopants of a first conductivity-type, wherein a doping concentration of the first epitaxial semiconductor layer 103 is different than the doping concentration of second epitaxial semiconductor layer 105.

In another embodiment, the method further includes forming a third epitaxial semiconductor layer 113 over the first epitaxial semiconductor layer 103.

In another embodiment, the third epitaxial semiconductor layer 113 includes the same material as the first epitaxial semiconductor layer 103 and has a third resistivity that is within 10% of the first resistivity of the first epitaxial semiconductor layer 103 or the second resistivity of the second epitaxial semiconductor layer 105.

An additional embodiment is drawn to a method of forming a semiconductor structure that includes forming a second epitaxial semiconductor layer 105 over a first epitaxial semiconductor layer 103 that is located on a first substrate 101, forming a first dielectric capping layer 106 over the second epitaxial semiconductor layer 105, bonding the first dielectric capping layer 106 to a second dielectric capping layer 111 located on a second substrate 110, removing the first substrate 101, and forming a third epitaxial semiconductor layer 113 over the first epitaxial semiconductor layer 103, where a resistivity of the third epitaxial semiconductor layer 113 is different than a resistivity of the second epitaxial semiconductor layer 105.

In an embodiment, a thickness of the third epitaxial semiconductor layer 113 is less than a thickness of the first epitaxial semiconductor layer 103 and a thickness of the second epitaxial semiconductor layer 105.

In another embodiment, a total thickness T of the first epitaxial semiconductor layer 103, the second epitaxial semiconductor layer 105, and the third epitaxial semiconductor layer 113 is between 4 μm and 12 μm.

In another embodiment, the resistivity of the second epitaxial semiconductor layer 105 is greater than the resistivity of the third epitaxial semiconductor layer 113 by at least a factor of five.

An additional embodiment is drawn to a semiconductor structure including a substrate 110, a buried insulator layer 112 over the substrate 110, and an epitaxial semiconductor material portion 115 over the buried insulator layer 112, where the epitaxial semiconductor material portion 115 includes a first epitaxial semiconductor layer 103 having a first resistivity, a second epitaxial semiconductor layer 105 having a second resistivity located between the buried insulator layer 112 and the first epitaxial semiconductor layer 103, and a third epitaxial semiconductor layer 113 having a third resistivity over the first epitaxial semiconductor layer 103, and the second resistivity differs from the first resistivity and the third resistivity by a factor of two or more.

In an embodiment, the second resistivity is greater than the first resistivity, and the third resistivity is within 10% of the first resistivity or the second resistivity.

In another embodiment, the semiconductor structure further includes at least one double diffused metal oxide semiconductor (DMOS) device 129, at least one bipolar device 131, and at least one complementary metal oxide semiconductor (CMOS) device 133 formed on, and/or within portions of, the epitaxial semiconductor material portion 115.

In another embodiment, the semiconductor structure has a breakdown voltage that is greater than 170 volts.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure, comprising:
a substrate;
a buried insulator layer over the substrate; and
an epitaxial semiconductor material portion over the buried insulator layer, wherein the epitaxial semiconductor material portion comprises:
a first epitaxial semiconductor layer having a first resistivity;
a second epitaxial semiconductor layer having a second resistivity located between the buried insulator layer and the first epitaxial semiconductor layer; and
a third epitaxial semiconductor layer having a third resistivity over the first epitaxial semiconductor layer, and the second resistivity differs from the first resistivity and the third resistivity by a factor of two or more.

2. The semiconductor structure of claim 1, wherein the second resistivity is greater than the first resistivity, and the third resistivity is within 10% of the first resistivity or the second resistivity.

3. The semiconductor structure of claim 1, further comprising:
at least one double diffused metal oxide semiconductor (DMOS) device, at least one bipolar device, and at least one complementary metal oxide semiconductor (CMOS) device formed on, and/or within portions of, the epitaxial semiconductor material portion.

4. The semiconductor structure of claim 3, wherein the semiconductor structure has a breakdown voltage that is greater than 170 volts.

5. The semiconductor structure of claim 1, wherein the second resistivity is greater than the first resistivity and the third resistivity by a factor of five or more.

6. The semiconductor structure of claim 1, wherein the second resistivity is greater than the first resistivity and the third resistivity by a factor of ten or more.

7. The semiconductor structure of claim 1, wherein the first epitaxial semiconductor layer, the second epitaxial semiconductor layer, and the third epitaxial semiconductor layer comprise crystalline semiconductor material.

8. The semiconductor structure of claim 1, wherein the first epitaxial semiconductor layer, the second epitaxial semiconductor layer, and the third epitaxial semiconductor layer comprise the same semiconductor material doped with dopants of a first conductivity-type, wherein a doping concentration of the second epitaxial semiconductor layer is different than a doping concentration of the first epitaxial semiconductor layer and a doping concentration of the third epitaxial semiconductor layer.

9. A semiconductor-on-insulator (SOI) structure, comprising:
a substrate;
a buried insulator layer over the substrate; and
an epitaxial semiconductor material portion over the buried insulator layer, wherein the epitaxial semiconductor material portion comprises:
a first epitaxial semiconductor layer having a first resistivity; and
a second epitaxial semiconductor layer having a second resistivity located between the buried insulator layer and the first epitaxial semiconductor layer,
wherein the epitaxial semiconductor material portion has a variable resistivity along a thickness dimension between an upper surface of the epitaxial semiconductor material portion and an interface between the second epitaxial semiconductor layer and the buried insulator layer.

10. The SOI structure of claim 9, wherein the second resistivity is greater than the first resistivity.

11. The SOI structure of claim 10, wherein the second resistivity is greater than the first resistivity by a factor of at least two.

12. The SOI structure of claim 9, wherein a thickness of the epitaxial semiconductor material portion is between 0.2 μm and 20 μm.

13. The SOI structure of claim 9, wherein the first epitaxial semiconductor layer has a thickness between 0.1 μm and 10 μm, and the second epitaxial semiconductor layer has a thickness between 0.1 μm and 10 μm.

14. The SOI structure of claim 9, wherein the buried insulator layer comprises at least one of silicon oxide, silicon nitride, silicon oxynitride, or aluminum oxide.

15. A semiconductor device, comprising:
a substrate;
a buried insulator layer over the substrate;
an epitaxial semiconductor material portion over the buried insulator layer, wherein the epitaxial semiconductor material portion comprises a first epitaxial semiconductor layer and a second epitaxial semiconductor layer located between the buried insulator layer and the first epitaxial semiconductor layer, and wherein a resistivity of the second epitaxial semiconductor layer is different than a resistivity of the first epitaxial semiconductor layer;
at least one high-voltage device formed on the epitaxial semiconductor material portion, the at least one high-voltage device having an operating voltage greater than 50 volts; and
at least one low-voltage device formed on the epitaxial semiconductor material portion, the at least one low-voltage device having an operating voltage less than 50 volts.

16. The semiconductor device of claim 15, wherein the at least one high-voltage device comprises at least one double diffused metal oxide semiconductor (DMOS) device.

17. The semiconductor device of claim 15, wherein the at least one low-voltage device comprises at least one of a bipolar junction transistor and a complementary metal oxide semiconductor (CMOS) field effect transistor.

18. The semiconductor device of claim 15, wherein the semiconductor device has a breakdown voltage that is at least 170 volts.

19. The semiconductor device of claim 15, wherein the epitaxial semiconductor material portion further comprises a third epitaxial semiconductor layer over the first epitaxial semiconductor layer, wherein a resistivity of the third epitaxial semiconductor layer is different than the resistivity of the second epitaxial semiconductor layer.

20. The semiconductor device of claim 15, further comprising an isolation structure located between the at least one high-voltage device and the at least one low-voltage device, wherein the isolation structure extends through at least a portion of the epitaxial semiconductor material portion.
